(19) United States
(12) Patent Application Publication
(10) Pub. No.: US 2009/0179781 A1
(43) Pub. Date: Jul. 16, 2009

(54) SHEET, KEYBOARD, AND ELECTRONIC APPARATUS

(75) Inventors: Satoshi SAKAI, Ishikawa (JP); Yoshiaki Fujimoto, Ishikawa (JP); Motoshi Shibuya, Ishikawa (JP); Akihisa Kozakura, Ishikawa (JP)

Correspondence Address: LOWE HAUPTMAN HAM & BERNER, LLP, 1700 DIAGONAL ROAD, SUITE 300, ALEXANDRIA, VA, 22314, US

(73) Assignee: PFU LIMITED, ISHIKAWA (JP)

(21) Appl. No.: 12/248,557

(22) Filed: Oct. 9, 2008

(30) Foreign Application Priority Data
Jan. 10, 2008 (JP) 2008-003726

(51) Int. Cl. H03K 17/94; G06F 17/20

(52) U.S. Cl. 341/23; 704/8

(57) ABSTRACT

A sheet or overlay has plasticity and covers a keyboard including a plurality of keys, provided with a standard key indication based on a given language environment. The sheet has regions facing the keys on the keyboard, and an optional key indication based on a language environment different from the given language environment is provided in the regions so as to be visible by an operator when the sheet covers the keyboard. If the operator's use language is different from a language of the standard key indication on the keyboard, the keyboard is covered by the sheet supporting the operator's use language. In this way, an electronic apparatus coupled to the keyboard is set to support the language environment of the operator.

### BACKGROUND OF THE INVENTION

1. Field of the Invention

The present invention relates to a sheet, a keyboard, and an electronic apparatus. The invention particularly relates to a sheet, a keyboard, and an electronic apparatus that support a multilingual environment.

2. Description of the Related Art

Recent years have seen widespread use of electronic apparatuses each supporting, as a single unit, use in a multilingual environment for a plurality of operators using different languages. For example, Japanese Patent Application Laid-open No. 11-203008 discloses a conventional technology including detecting a use language necessary for a user (operator) operating a keyboard, switching to an environment of the use language thus detected, and controlling and displaying screen image information on a display based on the environment of the use language. This allows automatic detection of and switching to an optimum language environment for the user (operator), enabling to provide the user with a user-friendly apparatus.

A keyboard is given different key indications for a plurality of keys constituting the keyboard, depending on language environments of operators. Specifically, a keyboard needs to have several or several tens of types of key indications for the keys, depending on language environments of a plurality of operators operating the keyboard. Thus, it has been necessary even for electronic apparatuses supporting use in a multilingual environment to prepare various types of keyboards to be operated by operators, based on the language environments of the operators.

An electronic apparatus supporting use in a multilingual environment and integrally provided with a keyboard, i.e., a keyboard-integrated electronic apparatus, basically includes a keyboard having a plurality of keys with key indications based on a standard language environment for each geographical area, where operators use the electronic apparatus. In multiethnic countries where operators use different languages even in the same geographical area, there is a need for providing, in one area, a plurality of electronic apparatuses with different types of keyboards. This poses a problem that a plurality of electronic apparatuses each having different keyboards need to be manufactured to support all the operators of the electronic apparatuses.

### SUMMARY OF THE INVENTION

It is an object of the present invention to at least partially solve the problems in the conventional technology.

According to an aspect of the present invention, a sheet covers a keyboard including a plurality of keys having a standard key indication based on a given language environment. The sheet has plasticity and regions facing the keys, and an optional key indication based on a language environment different from the given language environment is provided in the regions so that the optional key indication is visible by an operator with the sheet covering the keyboard.

According to another aspect of the present invention, a keyboard is covered by a sheet and includes a plurality of keys having a standard key indication based on a given language environment. The sheet has plasticity, an entirely flat surface, and regions facing the keys, and an optional key indication based on a language environment different from the given language environment is provided in the regions so that the optional key indication is visible by an operator with the sheet covering the keyboard. The keyboard includes a positioning member that positions the sheet relative to the keyboard.

According to still another aspect of the present invention, an electronic apparatus is integrated with a keyboard that is covered by a sheet and includes a plurality of keys having a standard key indication based on a given language environment. The sheet has plasticity, an entirely flat surface, and regions facing the keys, and an optional key indication based on a language environment different from the given language environment is provided in the regions so that the optional key indication is visible by an operator with the sheet covering the keyboard. The keyboard includes a positioning member that positions the sheet relative to the keyboard. The electronic apparatus is capable of supporting use in a multilingual environment.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic of an electronic apparatus according to an embodiment of the present invention;

FIG. 2 is a schematic block diagram of the electronic apparatus according to the embodiment;

FIG. 3 is a specific layout of a keyboard according to the embodiment;

FIGS. 4A to 4C are enlarged views of protrusions according to the embodiment;

FIG. 5 is a layout of a sheet (English (UK));

FIG. 6 is a schematic of a rear surface of the sheet shown in FIG. 5;

FIG. 7 is a layout of another sheet (German);

FIG. 8 is a layout of another sheet (Italian);

FIG. 9 is a layout of another sheet (Spanish);

FIG. 10 is a layout of another sheet (French);

FIG. 11 is a flowchart of a method for setting the electronic apparatus according to the embodiment to support a language environment of an operator;

FIG. 12 is a schematic of the keyboard covered by a sheet;

FIG. 13 is a flowchart of initial setting;

FIG. 14 depicts a screen image for initial setting;

FIG. 15 depicts a screen image for initial setting;

FIG. 16 depicts a screen image for initial setting;

FIG. 17 depicts a screen image for initial setting; and

FIG. 18 depicts a login screen image.

### DETAILED DESCRIPTION OF THE PREFERRED EMBODIMENTS

Exemplary embodiments of the present invention will now be described with reference to the accompanying drawings. The present invention is not limited by the following embodiments. The embodiments include elements that can be easily achieved by one skilled in the art, or elements that are substantially equivalent to those described herein. The embodiments describe an electronic apparatus integrated with a keyboard, for example, a keyboard-integrated electronic apparatus capable of supporting use in a multilingual environment and incorporating an image scanner unit that can read an image on a recording medium, such as an original. The present invention, however, is not limited to this and may be applied to a keyboard-integrated electronic apparatus not incorporating an image scanner unit, or to an electronic apparatus coupled to a separately provided keyboard.

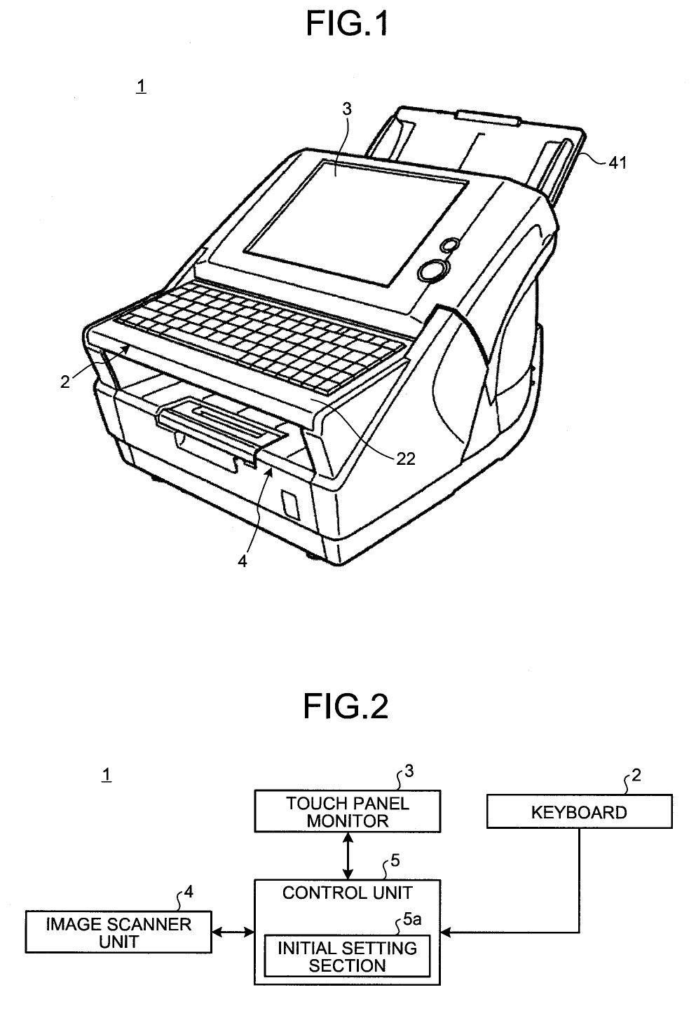

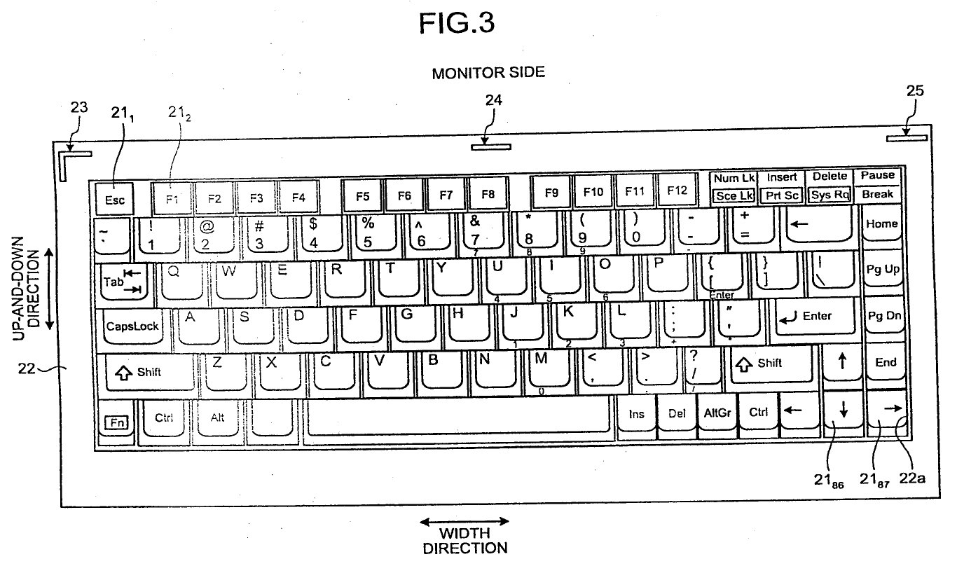

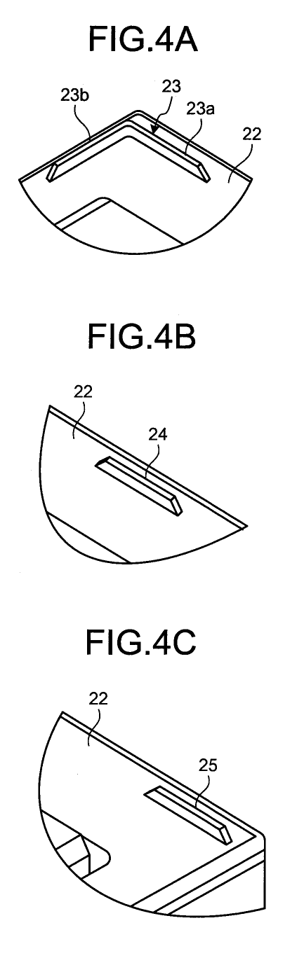

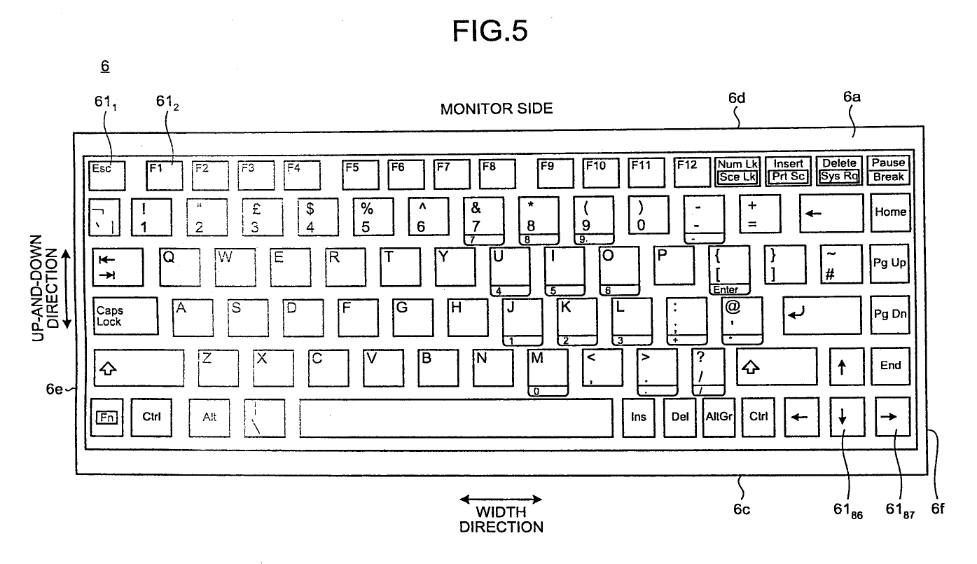

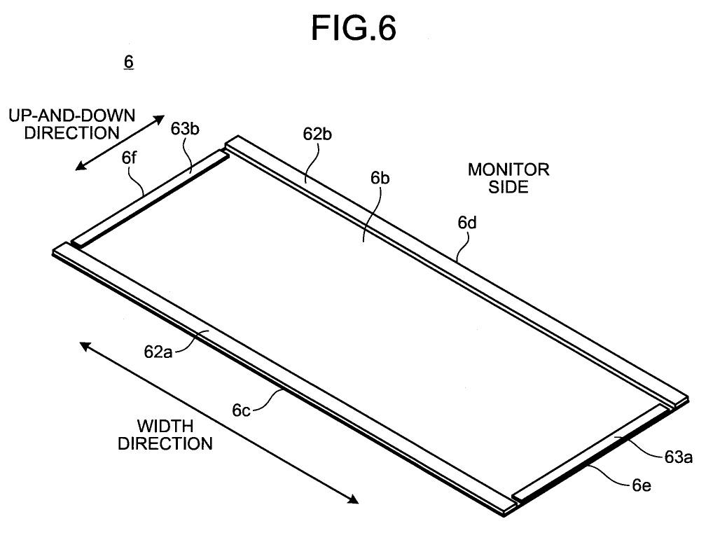

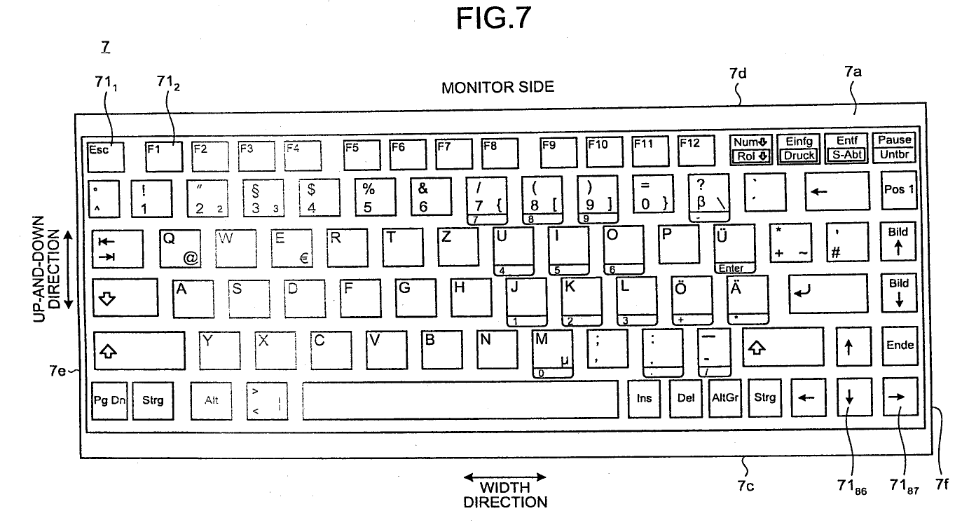

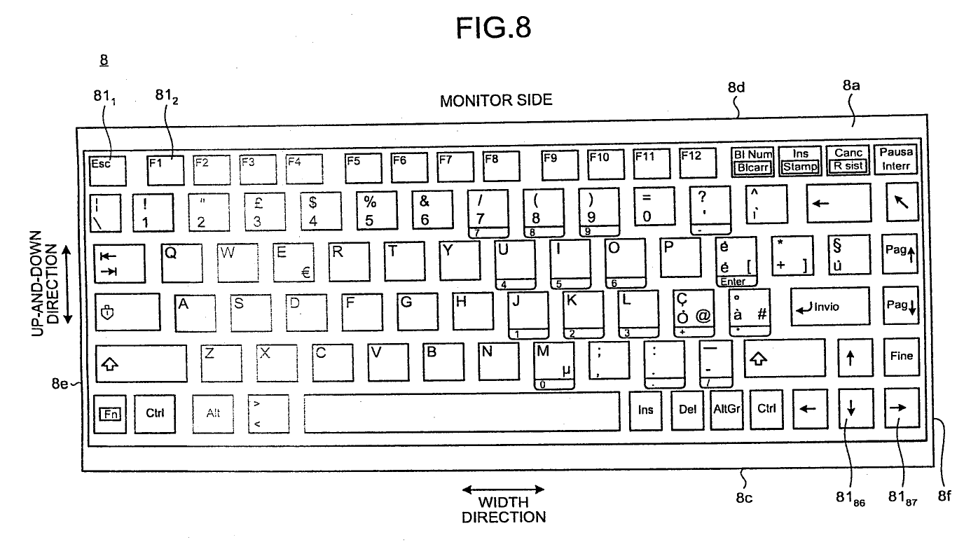

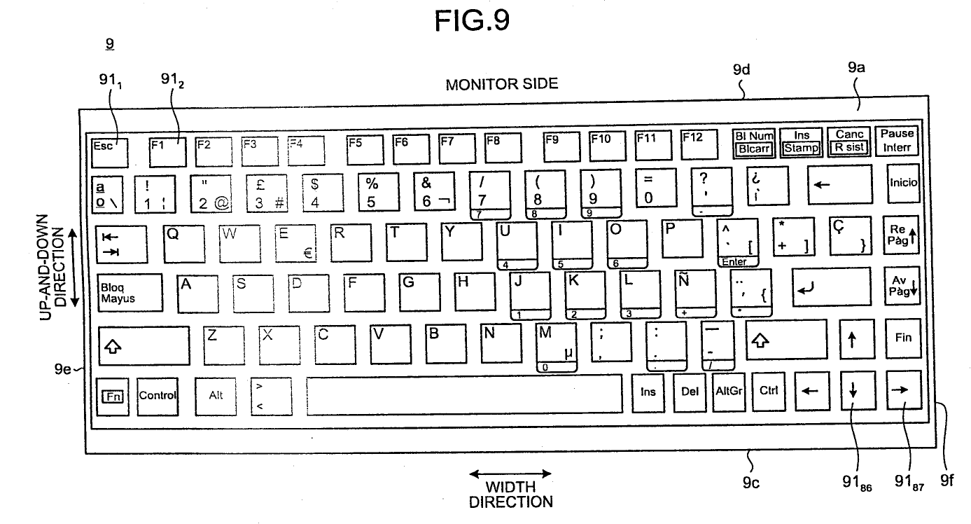

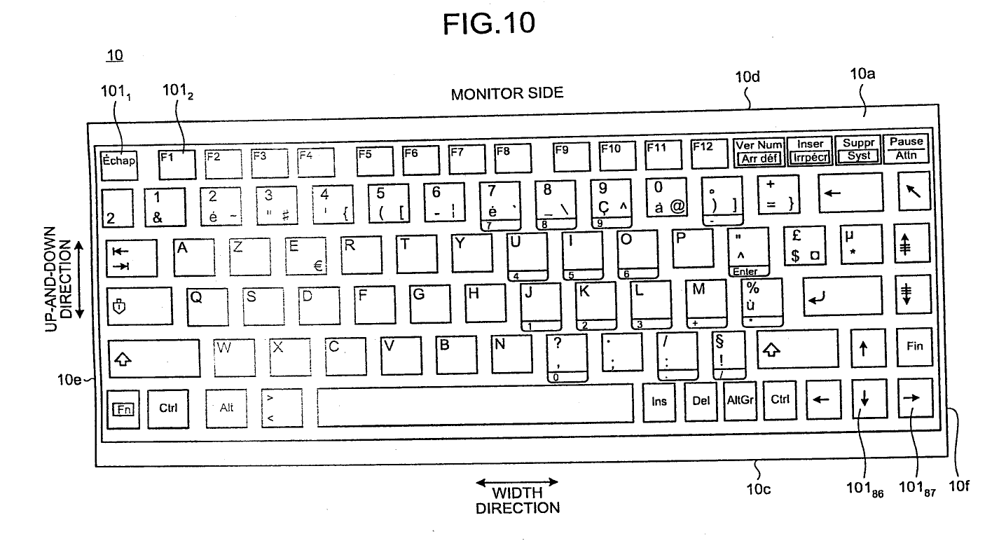

FIG. 1 is a schematic of an electronic apparatus according to an embodiment of the present invention. FIG. 2 is a schematic block diagram of the electronic apparatus. FIG. 3 is a specific layout of a keyboard. FIGS. 4A to 4C are enlarged views of protrusions. FIG. 5 is a layout of a sheet (English (UK)). FIG. 6 is a schematic of a rear view of the sheet. FIG. 7 is a layout of another sheet (German (used in Germany)). FIG. 8 is a layout of another sheet (Italian). FIG. 9 is a layout of another sheet (Spanish). FIG. 10 is a layout of another sheet (French). As shown in FIGS. 1 and 2, an electronic apparatus 1 according to the present embodiment includes a keyboard 2, a touch panel monitor 3, an image scanner unit 4, and a control unit 5, all integrally provided.

The keyboard 2 is placed in the electronic apparatus 1 to be visible by an operator of the electronic apparatus 1. As shown in FIG. 2, the keyboard 2 is coupled to the control unit 5. As shown in FIG. 3, the keyboard 2 includes a plurality of keys, i.e., 87 keys: keys 21₁ to 21₈₇ in the present embodiment. The keyboard 2 is operated by the operator. When each of the keys 21₁ to 21₈₇ is pressed by the operator, an electronic signal corresponding to each of the keys 21₁ to 21₈₇ is output to the control unit 5. All the keys 21₁ to 21₈₇ are arranged within an area surrounded by a square clearance 22a formed in a keyboard casing 22. In the present embodiment, the clearance 22a has a rectangular shape extending along a width direction shown in FIG. 3. The keys 21₁ to 21₈₇ have a standard key indication based on a given language environment. In the present embodiment, the keys 21₁ to 21₈₇ have a key indication supporting US English. As the keys 21₁ to 21₈₇, keys with small projections and depressions are used in the present embodiment. Thus, upper surfaces of the keys 21₁ to 21₈₇ position at the same level or substantially the same level as an upper surface of the keyboard casing 22, so that the keyboard 2 has a substantially flat shape.

The keyboard 2 includes protrusions 23 to 25. The protrusions 23 to 25 serve as positioning members that position a sheet or overlay 6 relative to the keyboard 2. The protrusions 23 to 25 are arranged linearly in the width direction so as to protrude from a portion, closer to a monitor than the clearance 22a (the keys 21₁ to 21₈₇), of the surface of the keyboard casing 22. On the keyboard casing 22, the protrusions 23 to 25 are placed so as to face an edge 6d, which is one of four edges 6c to 6f of the sheet 6, when covered by the sheet 6 (described later).

Among the protrusions 23 to 25, the protrusion 23 is provided at one of two width-direction ends (i.e., a left edge in FIG. 3). As shown in FIG. 4A, the protrusion 23 includes a first protruded portion 23a extending along the width direction, and a second protruded portion 23b extending along an up-and-down direction from an outer width-direction end of the first protruded portion. Specifically, the protrusion 23 is provided in an L shape so that the first protruded portion 23a faces one edge 6d and the second protruded portion 23b faces another edge 6e continued from the edge 6d when covered by the sheet 6 (described later).

The protrusion 24 is provided at the center of the protrusions 23 to 25 in the width direction. As shown in FIG. 4B, the protrusion 24 is provided in a bar-like shape extending along the width direction and facing the edge 6d when covered by the sheet 6 (described later).

The protrusion 25 is provided on the other of the two width-direction ends (i.e., a right edge in FIG. 3). As shown in FIG. 4C, the protrusion 25 is provided in a bar-like shape extending along the width direction and facing the edge 6d when covered by the sheet 6 (described later)

As shown in FIGS. 1 and 2, the touch panel monitor 3 is placed in the electronic apparatus 1 to be visible by the operator operating the electronic apparatus 1. In the present embodiment, the touch panel monitor 3 is provided above the keyboard 2. The touch panel monitor 3 is coupled to the control unit 5, and displays various screen images based on image signals output from the control unit 5. When the operator presses a predetermined position on the touch panel monitor 3, an electronic signal corresponding to that position is output to the control unit 5.

The image scanner unit 4 reads an image on a recording medium with an imaging sensor, as shown in FIGS. 1 and 2. The image scanner unit 4 is coupled to the control unit 5, and includes an imaging sensor, a light source (both not shown), and a paper feed unit 41. When an image on a recording medium, an original P, is read with the image scanner unit 4, the light source provided inside the electronic apparatus 1 lights up, and the original P set in the paper feed unit 41 is conveyed in a conveying direction by the paper feed unit 41. The imaging sensor provided inside the electronic apparatus 1 outputs to the control unit 5 an electronic signal as an output corresponding to light reflected from the original P, conveyed in the conveying direction by the paper feed unit 41 and irradiated with light from the light source.

The control unit 5 controls the electronic apparatus 1. For example, the control unit 5 selects a screen image to be displayed on the touch panel monitor 3, or drives and controls the image scanner unit 4. The control unit 5 stores therein a control program for controlling the electronic apparatus 1. The control program enables the electronic apparatus 1 to support use in a multilingual environment. The control program controls the electronic apparatus 1 using a standard language. For example, when the operator presses each of the keys 21₁ to 21₈₇, the control unit 5 determines that an electronic signal corresponding to each of the keys 21₁ to 21₈₇, output to the control unit 5, is an input based on a key indication on the keyboard 2 in a standard language environment. The control unit 5 outputs an image display signal for the standard language to the touch panel monitor 3, so that a screen image based on the standard language is displayed on the touch panel monitor 3. The standard language is either a language set in advance as factory default, i.e., US English in the present embodiment, or a language selectively set by the operator at an initial setting (described later). The control unit 5 has a hardware structure including a central processing unit (CPU) that mainly performs arithmetic processing, memories (a random access memory (RAM) and a read only memory (ROM)) that store therein computer programs and information, and an input/output interface. Such structure is the same as those of known personal computers and scanners, and detailed descriptions thereof are omitted. The control unit 5 may be coupled to other electronic apparatuses via a local area network (LAN). Thus, the electronic apparatus 1 may function as a network scanner.

The control unit 5 includes an initial setting section 5a. The initial setting section 5a allows the operator to select a standard language, for example, when the electronic apparatus 1 is initially started up after shipment. The operator selects a standard language, i.e., a use language, with the initial setting section 5a, so that the control program controls the electronic apparatus 1 using the standard language. Note that the control unit 5 has been initialized with the standard language set as factory default. In the present embodiment, the control unit 5 has been initialized with US English, so that the control program controls the electronic apparatus 1 using US English. Thus, when the operator presses each of the keys 21₁ to 21₈₇ for example, the control unit 5 determines that an electronic signal corresponding to each of the keys 21₁ to 21₈₇, output to the control unit 5, is an input based on a key indication supporting US English. The control unit 5 outputs an image display signal for US English to the touch panel monitor 3, so that a screen image based on US English is displayed on the touch panel monitor 3.

The sheet 6 having plasticity covers the keyboard 2. The sheet 6 has plasticity because it is made of sheet material such as nylon, polyurethane, or silicon. As shown in FIGS. 5 and 6, the sheet 6 has a square contour, i.e., a rectangular extending along the width direction in the present embodiment. Further, the sheet 6 is formed to be larger than the clearance 22a of the keyboard casing 22. Thus, when the sheet 6 covers the keyboard 2 such that a center portion of the sheet 6 coincides with a center portion of the clearance 22a, a rear surface 6b along the four edges 6c to 6f of the sheet 6 faces a portion around the clearance 22a on the surface of the keyboard casing 22.

The sheet 6 is entirely formed in a flat shape. As in the keyboard 2 according to the present embodiment, when the keys constituting the keyboard 2 have small projections and depressions and therefore the keyboard 2 has a substantially flat shape, covering the keyboard 2 with the sheet 6 having an entirely flat shape and plasticity suppresses increase in gap size between the keys 21₁ to 21₈₇ and the sheet 6. Thus, even when the operator presses the keys 21₁ to 21₈₇ via the sheet 6, the operator can feel less uncomfortable than when directly pressing the keys 21₁ to 21₈₇. This ensures key touch operation even with the sheet 6.

On the sheet 6, an optional key indication supporting a language environment different from a given language environment is provided in regions 61₁ to 61₈₇ that respectively face the keys 21₁ to 21₈₇ when covering the keyboard 2. In the present embodiment, an optional key indication supporting UK English, which is different from US English, is provided in the regions 61₁ to 61₈₇. The optional key indication is provided in the regions 61₁ to 61₈₇ so as to be visible by the operator when the keyboard 2 is covered by the sheet 6. Specifically, the optional key indication is provided by rear panel silk screen printing in the regions 61₁ to 61₈₇ on the reverse side of the side visible by the operator, i.e., on the rear surface 6b of the sheet 6, so as to be visible from above an upper surface 6a of the sheet 6. With this configuration, the optional key indication is positioned between the sheet 6 and the keyboard 2 when the keyboard 2 is covered by the sheet 6, and not exposed outside. Thus, for example, the operator does not directly touch the optional key indication when operating the keyboard 2. Further, even when some liquid is attached to the upper surface 6a of the sheet 6, the liquid is not directly attached to the optional key indication. This increases durability of the optional key indication of the sheet 6. Further, because the optional key indication is printed on the rear surface, the transparency and texture are improved. The sheet 6 is preferably formed of transparent or semi-transparent sheet material. Such material allows the operator see the gap between the regions 61₁ to 61₈₇ on the upper surface 6a of the sheet 6 and the keys 21₁ to 21₈₇ when the keyboard 2 is covered by the sheet 6, enabling to suppress an appearance difference from the keyboard not covered by the sheet 6. Further, because keyboard 2 is visible through the sheet 6, positioning is easy when covering the keyboard 2 by the sheet 6.

As shown in FIG. 6, among the four edges 6c to 6f of the sheet 6, the two facing edges 6c and 6d are provided with double-stick tapes 62a and 62b, and the two facing edges 6e and 6f are provided with supporting members 63a and 63b, all provided on the rear surface 6b of the sheet 6.

The double-stick tapes 62a and 62b are fixing members that fix the sheet 6 to the keyboard 2. The double-stick tapes 62a and 62b also serve as supporting members. The double-stick tapes 62a and 62b having elasticity are plate members provided on the rear surface 6b to extend along the edges 6c and 6d. Each of the double-stick tapes 62a and 62b has a thickness that provides elasticity, for example. Two opposed adhesive surfaces extending along each of the edges 6c and 6d of the double-stick tapes 62a and 62b have adhesive layers formed thereon that can be used repeatedly. One of the adhesive surfaces of the double-stick tape 62a is brought into contact with the rear surface 6b along the edge 6c in advance, so that the double-stick tape 62a is fixed to the edge 6c. One of the adhesive surfaces of the double-stick tape 62b is brought into contact with the rear surface 6b along the edge 6d in advance, so that the double-stick tape 62b is fixed to the edge 6d. Further, tape protective sheeting is attached to the other adhesive surfaces of the double-stick tapes 62a and 62b. Thus, when the keyboard 2 is covered by the sheet 6, the tape protective sheeting is removed, and the other adhesive surfaces of the double-stick tapes 62a and 62b serving as the fixing members are brought into contact with the surface of the keyboard casing 22 of the keyboard 2. In this way, the sheet 6 can be fixed to the keyboard 2 when the keyboard 2 is covered by the sheet 6. This suppresses relative displacement of the sheet 6 on the keyboard 2, enabling to suppress deviation of the sheet 6 from the keyboard 2. Further, because the double-stick tapes 62a and 62b can be used repeatedly, the sheet 6 can be fixed to the keyboard 2 repeatedly when the keyboard 2 is covered by the sheet 6.

The supporting members 63a and 63b having elasticity are plate members provided to extend along the edges 6e and 6f. Each of the supporting members 63a and 63b has a thickness that provides elasticity, for example. The supporting members 63a and 63b are formed to have a thickness smaller than that of the double-stick tapes 62a and 62b. The supporting member 63a is fixed to the rear surface 6b along the edge 6e with an adhesive agent or the like. The supporting member 63b is fixed to the rear surface 6b along the edge 6f with an adhesive agent or the like. In the present embodiment, all the edges 6c to 6f of the sheet 6 are provided with the supporting members. The supporting members provided along all the edges 6c to 6f allow an appropriate tension to be maintained on the sheet 6 that is deformable into any shape due to its elasticity. Accordingly, when the keyboard 2 is covered by the sheet 6, it becomes possible to suppress deviation of the regions 61₁ to 61₈₇ from the keys 21₁ to 21₈₇ due to deformation of the sheet 6. Thus, the optional key indication can be securely positioned to the keys 21₁ to 21₈₇.

In addition to the sheet 6 having the regions 61₁ to 61₈₇ with the optional key indication supporting UK English, sheets for supporting language environments other than the above-described sheets supporting US English and UK English are prepared in advance for a single electronic apparatus 1. Examples of such sheets include: a sheet 7 having regions 71₁ to 71₈₇ provided with an optional key indication supporting German used in Germany (hereinafter, “German”) (see FIG. 7), a sheet 8 having regions 81₁ to 81₈₇ provided with an optional key indication supporting Italian (see FIG. 8), a sheet 9 having regions 91₁ to 91₈₇ provided with an optional key indication supporting Spanish (See FIG. 9), and a sheet 10 having regions 10₁₁ to 101₈₇ provided with an optional key indication supporting French (see FIG. 10). In the sheets 7 to 10, double-stick tapes and supporting members (both not shown), equivalent to the double-stick tapes 62a and 62b and the supporting members 63a and 63b for the sheet 6, are provided on rear surfaces along edges 7c to 7f, 8c to 8f, 9c to 9f, and 10c to 10f. Further, sheet protective sheeting is attached to upper surfaces 6a to 10a of the sheets 6 to 10. From among the sheets 6 to 10, the operator selects a sheet supporting a language environment of the operator. Then, when the keyboard 2 is covered by the sheet selected from the sheets 6 to 10, the operator removes sheet protective sheeting and tape protective sheeting, and fixes the sheet thus selected to the keyboard 2. On such sheet protective sheeting, language environments supporting the respective sheets 6 to 10 are written in text, symbols, or figures so that the operator can understand the languages.

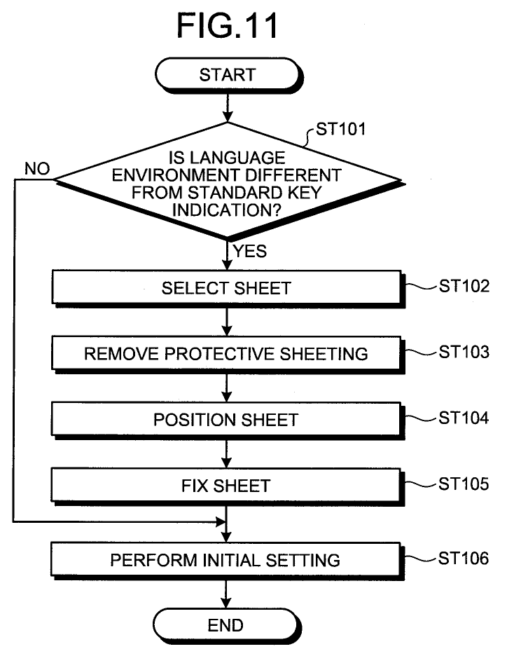

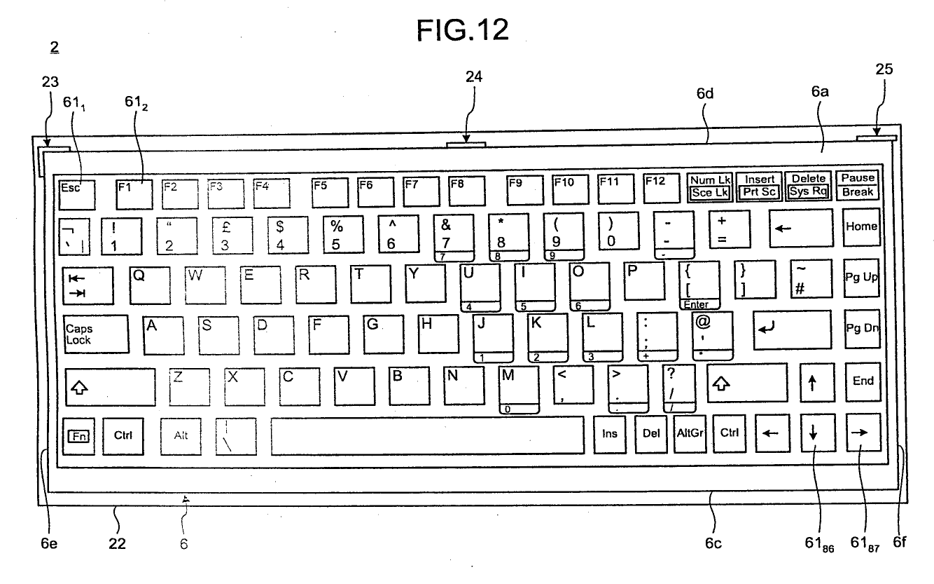

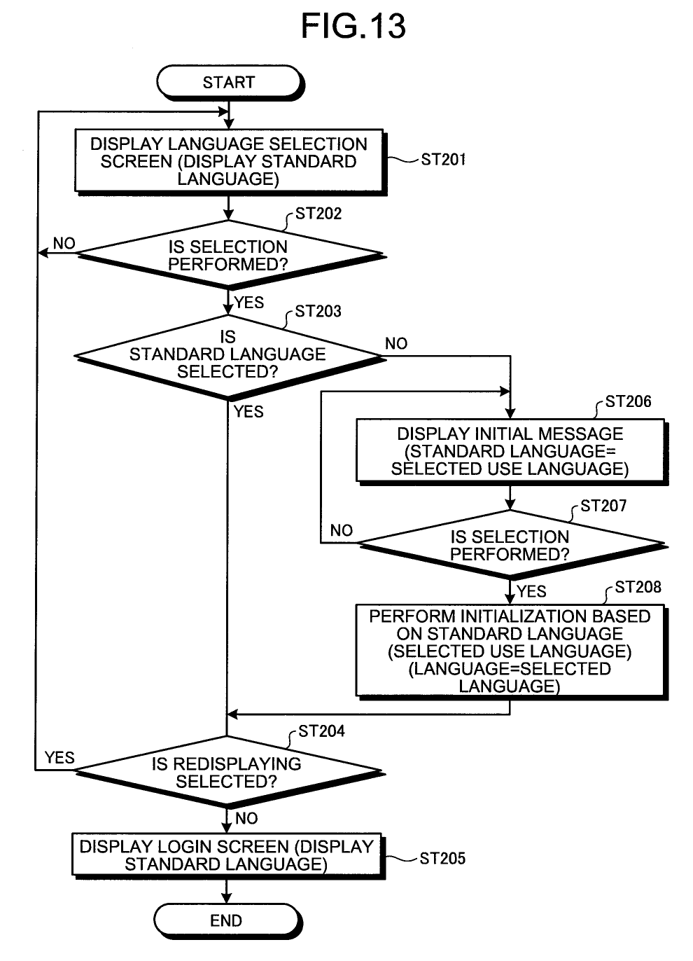

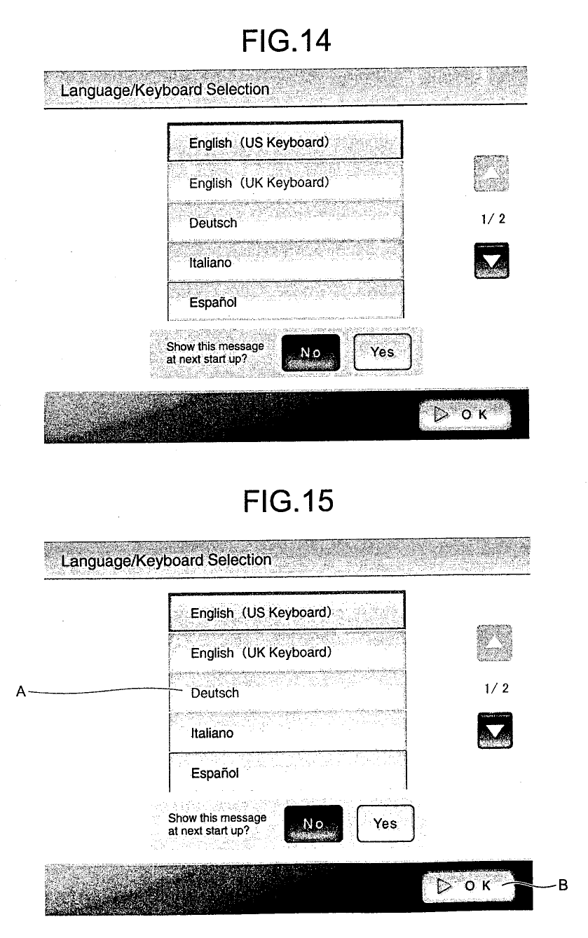

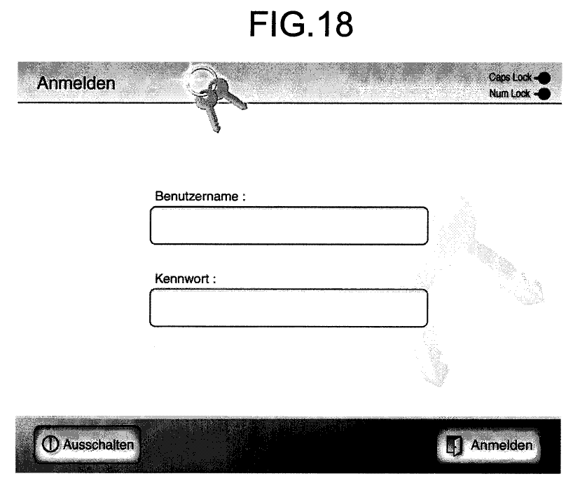

The following describes a method for setting the electronic apparatus 1 to support a language environment of the operator. FIG. 11 is a flowchart of a method for setting the electronic apparatus 1 to support a language environment of the operator. FIG. 12 is a schematic of a keyboard covered by a sheet. FIG. 13 is a flowchart of initial setting. FIGS. 14 to 17 depict screen images for initial setting. FIG. 18 depicts a login screen image.

To begin with, determination is made as to whether a language environment of the operator is different from a language environment of a standard key indication on the keyboard 2 (Step ST101). Specifically, determination is made as to whether the operator's language environment is different from a language set in advance as factory default, i.e., US English in the present embodiment. In other words, it is determined whether the electronic apparatus 1 can be used with the standard language set as factory default.

If the operator's language environment is different from the standard key indication on the keyboard 2 (YES at Step ST101), the operator selects a sheet supporting the operator's language environment (Step ST102). In the present embodiment, the operator selects a sheet supporting the operator's language environment, from among sheets supporting language environments other than US English prepared in advance for the electronic apparatus 1. For example, if an operator working in UK uses English, the operator selects the sheet 6. On the contrary, if the operator's language environment is the same as the standard key indication on the keyboard 2 (NO at Step ST101), the operator performs initial setting (Step ST106).

The operator then removes protective sheeting of the selected sheet (Step ST103). In the present embodiment, the operator removes sheet protective sheeting attached to the upper surface 6a of the sheet 6, and tape protective sheeting attached to the double-stick tape 62b. Thus, tape protective sheeting attached to the double-stick tape 62a is not removed.

The operator then positions the sheet (Step ST104). Specifically, the operator positions the sheet with the protective sheeting removed relative to the keyboard 2. In the present embodiment, the operator positions the edge 6d of the sheet 6 so that one width-direction end thereof, continued from the edge 6e, is brought into contact with the protrusion 23, and thus attaches the width-direction end to a portion, close to the monitor, of the upper surface of the keyboard casing 22. Specifically, the operator first positions the edge 6d of the sheet 6 to be brought into contact with the first protruded portion 23a of the protrusion 23, and the edge 6e to be brought into contact with the second protruded portion 23b of the protrusion 23, so as to attach part of the sheet 6 to the keyboard 2. The operator then positions the edge 6d of the sheet 6 so that the center portion thereof is brought into contact with the protrusion 24, and that the other width-direction end of the edge 6d is positioned to the protrusion 25. In this way, the center portion and the other end of the sheet 6 are attached to that portion, close to the monitor, of the upper surface of the keyboard casing 22. As such, the edges 6d and 6e of the sheet 6 are positioned with the protrusions 23 to 25, so that the edge 6d is attached to the keyboard 2 with the double-stick tape 62b. With the double-stick tape 62b, an appropriate tension can be maintained on the sheet 6 having elasticity. Thus, the operator can easily position the sheet 6 relative to the protrusions 23 to 25, and attach the sheet 6 to the electronic apparatus 1 across the width direction.

The operator then fixes the sheet (Step ST105). In the present embodiment, the operator covers the keyboard 2 with the sheet 6, and fixes the sheet 6 to the keyboard casing 22 with the double-stick tapes 62a and 62b. As described, the edge 6d of the sheet 6 is already attached to the keyboard casing 22 with the double-stick tape 62b, and now the tape protective sheeting attached to the double-stick tape 62a is removed. The operator attaches the edge 6c of the sheet 6 to a portion of the surface of the keyboard casing 22, opposite the portion close to the monitor. In this way, the sheet 6 is attached to the keyboard 2 with the double-stick tapes 62a and 62b and the keyboard 2 is covered by the sheet 6, in a manner shown in FIG. 12. Because the sheet 6 is positioned with the protrusions 23 to 25 to cover the keyboard 2, the regions 61₁ to 61₈₇ of the sheet 6 face the keys 21₁ to 21₈₇ of the keyboard 2, respectively. In this way, the keyboard 2 can be covered by the sheet 6 with the two edges 6d and 6e of the sheet 6 positioned to the protrusions 23 to 25, so that the sheet 6 can be securely positioned to the keyboard 2 in two directions, i.e., in the width direction and the up-and-down direction. Further, with the double-stick tape 62a and the supporting members 63a and 63b, an appropriate tension can be maintained on the sheet 6 having plasticity. This allows the sheet 6 to be attached in the up-and-down direction of the electronic apparatus 1.

The operator then performs initial setting (Step ST106). The operator performs the initial setting both when the operator's language environment is the same as the standard key indication on the keyboard 2 (i.e., the use language is the same as the standard language), and when the operator's language environment is different from the standard key indication on the keyboard 2 (i.e., the use language is different from the standard language) and the keyboard is covered by the sheet 6.

In the initial setting, when the operator starts the electronic apparatus 1, the control unit 5 displays a language selection screen on the touch panel monitor 3 as shown in FIG. 13 (Step ST201). Specifically, when the operator initially starts the electronic apparatus 1 after shipment, the control unit 5 displays a language selection screen on the touch panel monitor 3. By outputting an image display signal for the standard language, the control unit 5 displays a language selection screen based on the standard language on the touch panel monitor 3. In the present embodiment, a language selection screen based on US English is displayed on the touch panel monitor 3 as shown in FIG. 14. In the language selection screen, the following items are displayed: Title bar, a plurality of language selection buttons used by the operator to select a use language, Yes and No buttons used by the operator to select whether to redisplay the initial setting, and OK button used by the operator to perform the subsequent process, as shown in FIG. 14. When the display is based on US English, Title bar, Yes and No buttons, OK button, and other items are displayed in English. The language selection buttons are displayed such that the standard language, i.e., US English, appears on the top. The language selection buttons are displayed in the respective use languages, and a cursor is moved in advance to a language button of the standard language and to No button, not Yes button.

The control unit 5 determines whether the operator has touched OK button (Step ST202). If the operator has not touched OK button (NO at Step ST202), the control unit 5 continues to display the language selection screen on the touch panel monitor 3 until the operator touches OK button.

If the use language is the same as the standard language, the operator touches none of the language selection buttons, leaving the cursor on a language selection button of the standard language, and then touches OK button. On the contrary, if the use language is different from the standard language, the operator selectively touches a language selection button of the operator's language from among the language selection buttons to place the cursor on the language selection button thus touched, and then touches OK button.

If the operator has touched OK button (YES at Step ST202), the control unit 5 determines whether the standard language is selected (Step ST203). Specifically, the control unit 5 determines on which one of the language selection buttones the cursor is placed. When the operator's language is the same as the standard language, the cursor is on the language selection button of the standard language. Thus, the control unit 5 determines that the standard language is selected (YES at Step ST203). On the contrary, if the operator's language is different from the standard language, the cursor is on a language selection button of the operator's language. Thus, the control unit 5 determines that the standard language is not selected (NO at Step ST203).

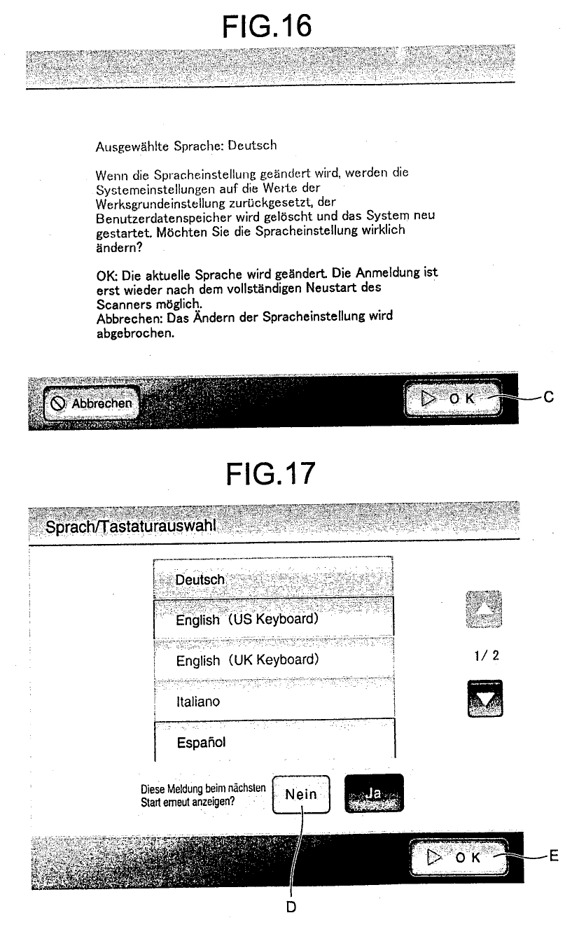

If the standard language is selected (YES at Step ST203), the control unit 5 determines whether redisplaying is selected (Step ST204). Specifically, if the cursor is on Yes button, not No button, displayed on the language selection screen, the control unit 5 determines that redisplaying is selected (YES at Step ST204) (see FIG. 16). On the contrary, if the cursor is on No button, the control unit 5 determines that redisplaying is not selected (NO at Step ST204).

If redisplaying is not selected (NO at Step ST204), the control unit 5 displays a login screen on the touch panel monitor 3 (Step ST205). By outputting an image display signal for the standard language, the control unit 5 displays a login screen based on the standard language on the touch panel monitor 3. In the present embodiment, when the standard language is selected, a login screen based on US English is displayed on the touch panel monitor 3. In the login screen, the following items are displayed: Title bar, Login entry for entering a login name, Password entry for entering a password, and OK button used by the operator to perform the subsequent process. When US English is the standard language as described, Title bar, Login entry, Password entry, OK button, and other items are displayed in English. Thus, the control program controls the electronic apparatus 1 using US English. With this configuration, the electronic apparatus 1 supporting use in a multilingual environment can support a language environment of the operator who uses US English. If redisplaying is selected (YES at Step ST204), the control unit 5 displays the language selection screen based on US English on the touch panel monitor 3 (Step ST201).

If the standard language is not selected (NO at Step ST203), the control unit 5 displays an initial message on the touch panel monitor 3 (Step ST206). Specifically, the control unit 5 displays an initial message written in the standard language on the touch panel monitor 3, by switching a use language selected by the operator (i.e., a use language of a language selection button where the cursor is placed) to the standard language, and then by outputting an image display signal for the standard language. For example, if an operator working in Germany uses German, the operator covers the keyboard 2 with the sheet 7 for German shown in FIG. 7, selectively touches a language selection button A for German from among the language selection buttons, and then touches OK button B as shown in FIG. 15. In this case, the standard language is switched from US English to German, and an initial message written in German is displayed on the touch panel monitor 3 as shown in FIG. 16. The initial message is displayed with Title bar and OK button used by the operator to perform the subsequent process. When the standard language is switched to German as described, Title bar, OK button, and other items are displayed in German.

As shown in FIG. 13, the control unit 5 determines whether the operator has touched OK button (Step ST207). If the operator has not touched OK button (NO at Step ST207), the control unit 5 continues to display the initial message on the touch panel monitor 3 until the operator touches OK button.

If the operator has touched OK button (YES at Step ST207), the control unit 5 is initialized with the standard language (Step ST208). Specifically, the control unit 5 is initialized with the use language selected by the operator, i.e., the standard language thus selected. For example, when the standard language is switched to German as described, the control unit 5 is initialized with German, so that the control program controls the electronic apparatus 1 using German. Thus, when the operator presses each of the keys 21₁ to 21₈₇ for example, the control unit 5 determines that an electronic signal corresponding to each of the keys 21₁ to 21₈₇, output to the control unit 5, is an input based on a key indication supporting German. The control unit 5 outputs an image display signal for German to the touch panel monitor 3, so that a screen image based on German is displayed on the touch panel monitor 3.

The control unit 5 then determines whether redisplaying is selected (Step ST204). Specifically, if the cursor is on Yes button, not No button, displayed on the language selection screen, the control unit 5 determines that redisplaying is selected (YES at Step ST204). On the contrary, if the cursor is on No button, the control unit 5 determines that redisplaying is not selected (NO at Step ST204).

If redisplaying is selected (YES at Step ST204), the control unit 5 displays a language selection screen based on German on the touch panel monitor 3 (Step ST201). For example, assume that an initial message written in German is displayed on the touch panel monitor 3, and then OK button C is touched as shown in FIG. 16. In this case, if the cursor is on Yes button as shown in FIG. 15, the language selection screen based on German is displayed on the touch panel monitor 3 as shown in FIG. 17. When the display is based on German, Title bar, Yes and No buttons, OK buttons, and other items are displayed in German, and the language selection buttons are displayed such that the standard language, i.e., German, appears on the top.

If redisplaying is not selected (NO at Step ST204), the control unit 5 displays a login screen on the touch panel monitor 3 (Step ST205). For example, assume that the operator touches No button D on the language selection screen to place the cursor on No button D, and then touches OK button as shown in FIG. 17. Accordingly, Title bar, Login entry, Password entry, OK button, and other items are displayed in German as shown in FIG. 18, so that the control program controls the electronic apparatus 1 using German. In this way, the electronic apparatus 1 supporting use in a multilingual environment can support the language environment of the operator who uses German.

As described, when the electronic apparatus 1 is operated by an operator whose language environment is different from a given language of a standard key indication, a sheet having an optional key indication based on the language environment of the operator of the electronic apparatus 1 is used to cover the keyboard 2. In this way, the key indication on the keyboard 2 is adapted to the language environment of the operator of the electronic apparatus 1, so that the electronic apparatus 1 is set based on the language environment of the operator. As a result, the electronic apparatus 1 supporting use in a multilingual environment can serve only with a single keyboard.

In the present embodiment, the sheet is entirely formed in a flat shape. The present invention is not limited to this, and the regions facing the keys 21₁ to 21₈₇ when covering the keyboard 2 may be formed to conform to the contour of the keys 21₁ to 21₈₇. Assume that the keys 21₁ to 21₈₇ constituting the keyboard 2 have large projections and depressions, and therefore the keyboard 2 has a non-flat surface. In this case, by covering the keyboard 2 with a sheet having plasticity and regions that face the keys 21₁ to 21₈₇ and that are formed to conform to the contour of the keys 21₁ to 21₈₇, it is possible to suppress increase in gap size between the keys 21₁ to 21₈₇ and the sheet. Thus, even when the operator presses the keys 21₁ to 21₈₇ via the sheet, the operator can feel less uncomfortable than when directly pressing the keys 21₁ to 21₈₇. This ensures improved key touch operation even with the sheet. Further, the regions facing the keys 21₁ to 21₈₇ are formed to conform to the contour of the keys 21₁ to 21₈₇. This suppresses relative displacement of the sheet on the keyboard 2, enabling to suppress deviation of the sheet from the keyboard 2.

In the present embodiment, a sheet is configured so that an optional key indication is visible from above the upper surface thereof. The present invention is not limited to this, and optional key indications may be provided on both the upper and the rear surfaces to support different language environments. In this case, the sheet needs to be formed of opaque sheet material. This allows a single sheet to have optional key indications supporting two language environments, enabling to suppress the number of sheets to be prepared in advance for a single electronic apparatus.

According to an embodiment of the present invention, a sheet achieves the following advantage. When a keyboard is operated by an operator whose language environment is different from a given language of a standard key indication, the keyboard is covered by a sheet having an optional key indication based on the language environment of the operator operating the keyboard. In this way, the key indication on the keyboard is adapted to the language environment of the operator operating the keyboard. By covering the keyboard with no sheet or with a sheet having an optional key indication based on the language environment of the operator operating the keyboard, key indications supporting a multilingual environment are realized on a single keyboard.

According to an embodiment of the present invention, a keyboard achieves the following advantage. Because a sheet can be positioned to the keyboard with positioning members, the keyboard can be covered even by a sheet having an entirely flat surface, without causing displacement between the keys and the regions facing the keys.

According to an embodiment of the present invention, an electronic apparatus achieves the following advantages. When the electronic apparatus is operated by an operator whose language environment is different from a given language of a standard key indication, a keyboard is covered by a sheet having a key indication based on the language environment of the operator of the electronic apparatus. In this way, the key indication on the keyboard is adapted to the language environment of the operator of the electronic apparatus, so that the electronic apparatus is set based on the language environment of the operator of the electronic apparatus. By covering the keyboard with no sheet or with a sheet having an optional key indication based on the language environment of the operator of the electronic apparatus, a multilingual environment can be supported by the keyboard in a single electronic apparatus integrated with therewith. Thus, it is possible to suppress production of electronic apparatuses that requires keyboards of different types to support all the operators of such electronic apparatuses.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A sheet that covers a keyboard including a plurality of keys having a standard key indication based on a given language environment, wherein
the sheet has plasticity and regions facing the keys, and an optional key indication based on a language environment different from the given language environment is provided in the regions so that the optional key indication is visible by an operator with the sheet covering the keyboard.

2. The sheet according to claim 1, wherein the regions respectively facing the keys with the sheet covering the keyboard are formed to conform a contour of the keys.

3. The sheet according to claim 1, wherein the sheet has an entirely flat surface.

4. The sheet according to claim 1, wherein the optional key indication is provided on a reverse side of a side visible by the operator.

5. The sheet according to claim 1, wherein the sheet includes a square contour having four edges, at least two facing edges of which have supporting members, respectively.

6. The sheet according to claim 5, wherein the supporting members are plate members extending along the at least two facing edges.

7. The sheet according to claim 1, wherein two facing edges of the four edges respectively have fixing members that fix the two facing edges to the keyboard.

8. The sheet according to claim 7, wherein the fixing members include double-stick tapes.

9. A keyboard that is covered by a sheet and includes a plurality of keys having a standard key indication based on a given language environment, wherein
the sheet has plasticity, an entirely flat surface, and regions facing the keys, and an optional key indication based on a language environment different from the given language environment is provided in the regions so that the optional key indication is visible by an operator with the sheet covering the keyboard, and
the keyboard comprises a positioning member that positions the sheet relative to the keyboard.

10. The keyboard according to claim 9, wherein the positioning member includes a plurality of protrusions provided to face one edge of the four edges of the sheet when covered by the sheet.

11. The keyboard according to claim 10, wherein, two of the protrusions are provided at both ends of the sheet, and at least one of the two is provided in an L shape so as to face the one edge and another edge continued from an end of the one edge.

12. The keyboard according to claim 9, wherein the keyboard is coupled to an electronic apparatus capable of supporting use in a multilingual environment.

13. An electronic apparatus which is integrated with a keyboard that is covered by a sheet and includes a plurality of keys having a standard key indication based on a given language environment, wherein
the sheet has plasticity, an entirely flat surface, and regions facing the keys, and an optional key indication based on a language environment different from the given language environment is provided in the regions so that the optional key indication is visible by an operator with the sheet covering the keyboard,
the keyboard comprises a positioning member that positions the sheet relative to the keyboard, and
the electronic apparatus is capable of supporting use in a multilingual environment.

14. The electronic apparatus according to claim 13, comprising an image scanner unit capable of reading an image on a recording medium.
